(19) United States
(12) Patent Application Publication
(10) Pub. No.: US 2024/0094621 A1
(43) Pub. Date: Mar. 21, 2024

(54) MASK BLANK AND REFLECTIVE MASK

(71) Applicant: HOYA CORPORATION, Tokyo (JP)

(72) Inventor: Kazutake TANIGUCHI, Tokyo (JP)

(73) Assignee: HOYA CORPORATION, Tokyo (JP)

(21) Appl. No.: 18/274,183

(22) PCT Filed: Feb. 8, 2022
(86) PCT No.: PCT/JP2022/004825

§ 371 Date: Jul. 25, 2023

(30) Foreign Application Priority Data
Feb. 25, 2021 (JP) 2021-028240

(51) Int. Cl. G03F 1/24; G03F 1/60; G03F 1/80

(52) U.S. Cl. CPC G03F 1/24; G03F 1/60; G03F 1/80

(57) ABSTRACT

A mask blank includes a substrate having a main surface on which a multilayer reflective film and the pattern-forming thin film are provided in this order. The thin film contains tantalum, niobium, and nitrogen. An X-ray diffraction pattern obtained by analyzing the thin film by Out-of-Plane measurement of X-ray diffraction satisfies the relationship of at least one of Imax1/Iavg1≤7.0 and Imax2/Iavg2≤1.0, where Imax1 is a maximum value of diffraction intensity at a diffraction angle 2θ in a range of 34 to 36 degrees, Iavg1 is an average value of diffraction intensity at a diffraction angle 2θ in a range 32 to 34 degrees, Imax2 is a maximum value of diffraction intensity at a diffraction angle 2θ of 40 to 42 degrees, and Iavg2 is an average value of diffraction intensity at a diffraction angle 2θ in a range of 38 to 40 degrees.

### CROSS-REFERENCE TO RELATED APPLICATIONS

This application is the National Stage of International Application No. PCT/JP2022/004825, filed Feb. 8, 2022, which claims priority to Japanese Patent Application No. 2021-028240, filed Feb. 25, 2021, and the contents of which is incorporated by reference.

### TECHNICAL FIELD

The present disclosure relates to a mask blank for an exposure mask used in manufacture of a semiconductor device or the like, a reflective mask which is a reflective exposure mask using the mask blank, and a method for manufacturing a semiconductor device using the reflective mask.

### BACKGROUND OF THE DISCLOSURE

Exposure devices in manufacture of semiconductor devices have advanced with a wavelength of a light source gradually shortened. In order to achieve transfer of a finer pattern, EUV lithography using extreme ultra violet (EUV: Extreme Ultra Violet, hereinafter called EUV light) having a wavelength around 13.5 nm has been developed. In the EUV lithography, a reflective mask is used because there are few materials transparent to the EUV light. Typical reflective masks include a reflective binary mask and a reflective phase shift mask (reflective halftone phase shift mask).

The reflective binary mask has, on a high reflective layer formed on a substrate, a relatively thick absorber pattern which sufficiently absorbs the EUV light. On the other hand, the reflective phase shift mask has, on a high reflective layer formed on a substrate, a relatively thin absorber pattern (phase shift pattern) which attenuates the EUV light by light absorption and which generates desired reflected light inverted in phase with respect to reflected light from the high reflective layer.

Patent Literatures 1 and 2 mentioned below describe techniques related to the reflective mask for the EUV lithography, and a mask blank for preparing the reflective mask.

Patent Literature 1 describes that a low reflective portion corresponding to the absorber pattern mentioned above has Ta (tantalum) and Nb (niobium) and further has any of Si (silicon), O (oxygen), and N (nitrogen). Patent Literature 1 describes that the low reflective portion has a lower absorbing film and an upper absorbing film each having low reflectivity and a multilayer structure and that the lower absorbing film mainly has a function of absorbing the EUV light as exposure light. Patent Literature 1 describes an example in which the lower absorbing film of Ta and Nb and the upper absorbing film of SiN are formed.

Patent Literature 2 relates to an absorbing film constituting the above-mentioned absorber pattern and describes that, with respect to the absorbing film containing Ta and nitrogen (N), a sufficient etching rate can be achieved during dry etching if a peak diffraction angle 2θ of a peak derived from a tantalum-based material in an X-ray diffraction pattern is 36.8 deg or more, and a half-value width of the peak derived from the tantalum-based material is 1.5 deg or more.

### PRIOR ART LITERATURE(S)

### Patent Literature(s)

Patent Literature 1: JP 2010-67757 A
Patent Literature 2: JP 2019-35929 A

### SUMMARY OF THE DISCLOSURE

### Problem to be Solved by the Disclosure

In the EUV lithography, the EUV light as the exposure light is obliquely incident to the reflective mask. This causes a unique problem called a shadowing effect to occur. The shadowing effect is a phenomenon in which the exposure light (EUV light) is obliquely incident to the absorber pattern having a three-dimensional structure to form a shadow, so that a transferred pattern is changed in size or position. In order to suppress the shadowing effect, it is necessary to reduce a thickness of an absorber film in the mask blank as an original plate of the reflective mask, thereby making the absorber pattern have a low profile.

However, the absorber film is required to have desired optical properties with respect to the exposure light. In particular, in a case of the reflective phase shift mask, it is necessary not only to simply reduce the thickness of the existing absorber film but also to reduce both a refractive index [n] and an extinction coefficient [k] of the absorber film with respect to the exposure light (EUV light). In order to achieve such optical properties, it is conceivable that the absorber film is formed of metal elements only. Generally, however, such thin film tends to have high crystallinity and large surface roughness. When the absorber pattern is formed by etching the thin film (absorber film) having high crystallinity and large surface roughness, edge roughness of the absorber pattern becomes large. As a result, in the EUV lithography using the reflective mask having the absorber pattern, transfer accuracy of the absorber pattern is significantly reduced. In addition, such thin film tends to have high film stress. When the absorber film having high film stress is formed on a substrate, the substrate is distorted. When the absorber film having high film stress is etched to form the absorber pattern, the absorber pattern is moved on the substrate and position accuracy of the absorber pattern is significantly reduced.

Accordingly, it is an aspect of the present disclosure to provide a mask blank having a pattern-forming thin film whose surface roughness and film stress are suppressed to be low.

It is also an aspect of the present disclosure to provide a reflective mask which is formed by using the mask blank.

It is a further aspect of the present disclosure to provide a method for manufacturing a semiconductor device by using the reflective mask.

### Means to Solve the Problem

In order to solve the above-mentioned problems, the present disclosure has the following configurations.

(Configuration 1)

A mask blank including a multilayer reflective film and a pattern-forming thin film which are formed on a main surface of a substrate in this order,
wherein the thin film contains tantalum, niobium, and nitrogen,
wherein an X-ray diffraction pattern obtained by analyzing the thin film by Out-of-Plane measurement of X-ray diffraction satisfies the relationship of at least one of Imax1/Iavg1≤7.0 and Imax2/Iavg2≤1.0, where Imax1 is a maximum value of diffraction intensity at a diffraction angle 2θ in a range of 34 to 36 degrees, Iavg1 is an average value of diffraction intensity at a diffraction angle 2θ in a range of 32 to 34 degrees, Imax2 is a maximum value of diffraction intensity at a diffraction angle 2θ in a range of 40 to 42 degrees, and Iavg2 is an average value of diffraction intensity at a diffraction angle 2θ in a range of 38 to 40 degrees.

(Configuration 2)

The mask blank according to Configuration 1, wherein, at a diffraction angle 2θ within a range of 30 degrees or more and 50 degrees or less in the X-ray diffraction pattern, the thin film has a maximum diffraction intensity at a diffraction angle 2θ of 38 degrees or less.

(Configuration 3)

The mask blank according to Configuration 1 or 2, wherein, in the thin film, a ratio of a content [atomic %] of niobium to a total content [atomic %] of tantalum and niobium is less than 0.6.

(Configuration 4)

The mask blank according to any one of Configurations 1 to 3, wherein a content of nitrogen in the thin film is 30 atomic % or less.

(Configuration 5)

The mask blank according to any one of Configurations 1 to 4, wherein a total content of tantalum, niobium, and nitrogen in the thin film is 95 atomic % or more.

(Configuration 6)

The mask blank according to any one of Configurations 1 to 4, wherein the thin film further contains boron.

(Configuration 7)

The mask blank according to Configuration 6, wherein a total content of tantalum, niobium, boron, and nitrogen in the thin film is 95 atomic % or more.

(Configuration 8)

The mask blank according to any one of Configurations 1 to 7, wherein a refractive index of the thin film at an extreme ultraviolet wavelength is 0.95 or less.

(Configuration 9)

The mask blank according to any one of Configurations 1 to 8, wherein an extinction coefficient of the thin film at an extreme ultraviolet wavelength is 0.03 or less.

(Configuration 10)

A reflective mask including a multilayer reflective film and a thin film with a transfer pattern formed on the multilayer reflective film are formed on a main surface of a substrate in this order,
wherein the thin film contains tantalum, niobium, and nitrogen,
wherein an X-ray diffraction pattern obtained by analyzing the thin film by Out-of-Plane measurement of X-ray diffraction satisfies the relationship of at least one of Imax1/Iavg1≤7.0 and Imax2/Iavg2≤1.0, where Imax1 is a maximum value of diffraction intensity at a diffraction angle 2θ in a range of 34 to 36 degrees, Iavg1 is an average value of diffraction intensity at a diffraction angle 2θ in a range of 32 to 34 degrees, Imax2 is a maximum value of diffraction intensity at a diffraction angle in a range 2θ of 40 to 42 degrees, and Iavg2 is an average value of diffraction intensity at a diffraction angle 2θ in a range of 38 to 40 degrees.

(Configuration 11)

The reflective mask according to Configuration 10, wherein, at a diffraction angle 2θ within a range of 30 degrees or more and 50 degrees or less in the X-ray diffraction pattern, the thin film has a maximum diffraction intensity at a diffraction angle 2θ of 38 degrees or less.

(Configuration 12)

The reflective mask according to Configuration 10 or 11, wherein, in the thin film, a ratio of a content [atomic %] of niobium to a total content [atomic %] of tantalum and niobium is less than 0.6.

(Configuration 13)

The reflective mask according to any one of Configurations 10 to 12, wherein a content of nitrogen in the thin film is 30 atomic % or less.

(Configuration 14)

The reflective mask according to any one of Configurations 10 to 13, wherein a total content of tantalum, niobium, and nitrogen in the thin film is 95 atomic % or more.

(Configuration 15)

The reflective mask according to any one of Configurations 10 to 13, wherein the thin film further contains boron.

(Configuration 16)

The reflective mask according to Configuration 15, wherein a total content of tantalum, niobium, boron, and nitrogen in the thin film is 95 atomic % or more.

(Configuration 17)

The reflective mask according to any one of Configurations 10 to 16, wherein a refractive index of the thin film at an extreme ultraviolet wavelength is 0.95 or less.

(Configuration 18)

The reflective mask according to any one of Configurations 10 to 17, wherein an extinction coefficient of the thin film at an extreme ultraviolet wavelength is 0.03 or less.

(Configuration 19)

A method for manufacturing a semiconductor device, the method comprising performing exposure transfer of a transfer pattern to a resist film on a semiconductor substrate using the reflective mask according to any one of Configurations 10 to 18.

### Effect of the Disclosure

According to the present disclosure, it is possible to provide a mask blank having a pattern-forming thin film whose surface roughness and film stress are suppressed to be low, a reflective mask which is formed by using the mask blank, and a method for manufacturing a semiconductor device by using the reflective mask.

### BRIEF DESCRIPTION OF THE DRAWINGS

FIG. 1 is a cross-sectional view showing a structure of a mask blank according to an embodiment of the present disclosure;

FIG. 2 is a cross-sectional view showing a configuration of a reflective mask according to the embodiment of the present disclosure;

FIG. 3 is a diagram showing an X-ray diffraction pattern for explaining physical properties of a thin film of the mask blank according to the embodiment of the present disclosure;

FIG. 4 is a graph (1) showing a composition of a tantalum (Ta)-niobium (Nb)-based material and a relationship between surface roughness and film stress;

FIG. 5 is a graph (2) showing the composition of the tantalum (Ta)-niobium (Nb)-based material and the relationship between the surface roughness and the film stress;

FIG. 6 is a graph (3) showing the composition of the tantalum (Ta)-niobium (Nb)-based material and the relationship between the surface roughness and the film stress;

FIGS. 7A to 7D are manufacturing process diagrams showing a method for manufacturing a reflective mask according to the present disclosure; and

FIG. 8 is a view showing forming conditions of thin films in examples of the present disclosure and comparative examples, and physical properties and compositions of the formed thin films.

### MODE FOR EMBODYING THE DISCLOSURE

Now, embodiments of the present disclosure will be described. First, a process leading to the present disclosure will be described. The inventors at first considered to use a material containing tantalum (Ta) and niobium (Nb) as an EUV light absorbing thin film in a mask blank for a reflective mask. However, the thin film formed of such a material has high crystallinity and is difficult to have a microcrystalline, more preferably an amorphous film property, as required for the EUV light absorbing thin film of the mask blank.

Therefore, the present inventors attempted to reduce both the crystallinity (surface roughness) of the film and film stress by making the EUV light absorbing thin film containing tantalum (Ta) and niobium (Nb) further contain nitrogen (N). However, after checking the tendency of the surface roughness and the film stress with respect to a composition (respective contents) of tantalum (Ta), niobium (Nb), and nitrogen (N) in the thin film, it cannot be said that correlation is high. Thus, it has been found out that the surface roughness of the film and the film stress are difficult to be reduced using the composition as an index. The reason is as follows. A pattern-forming thin film in the mask blank is formed by sputtering. In film formation by sputtering, an environment (flow rate of a sputtering gas, a sputtering gas pressure, etc.) in a film formation chamber is assumed to give a large influence on the crystallinity and the film stress of the thin film to be formed.

However, even if the environment in the film formation chamber is specified so that the surface roughness and the film stress of the thin film fall within a suitable range, those parameters are unique to a film forming apparatus used for the film formation and, when they are applied to other film forming apparatuses, the same properties are not necessarily obtained. Furthermore, there is a problem that measuring the surface roughness and the film stress of each thin film after formed requires a substantial effort.

In view of the above, the present inventors conducted further intensive studies on these problems. As a result, it has been found out in the following manner that an X-ray diffraction pattern obtained by measuring the thin film using X-ray diffraction provides an index of the surface roughness and the film stress of the thin film. The X-ray diffraction pattern is a graph representing an X-ray intensity [CPS] for each diffraction angle 2θ [deg], and is assumed herein to be an X-ray diffraction pattern in a case where analysis by Out-of-Plane measurement is carried out.

First, in an X-ray diffraction pattern obtained for the EUV light absorbing thin film, attention was focused on a maximum peak intensity occurring in the vicinity (34-36 [deg] and 40-42 [deg]) of a position of the diffraction angle 2θ corresponding to tetraniobium trinitride (Nb₄N₃). However, the intensity of the X-ray diffraction is easily varied depending on measurement conditions and is difficult to be directly used as the index. Then, as a result of further consideration, reached was an idea of using, as the index, a ratio [Imax/Iavg] obtained by dividing the maximum peak intensity [Imax] occurring in the vicinity of the position of the diffraction angle 2θ corresponding to tetraniobium trinitride (Nb₄N₃) by an average value [Iavg] of X-ray intensities [CPS] in a region of the diffraction angle 2θ [deg] in which the effect of the peak corresponding to tetraniobium trinitride (Nb₄N₃) is relatively small.

Two ratios may be used as the index. The first ratio is a ratio [Imax1/Iavg1] obtained by dividing a maximum peak intensity [Imax1] in a range (34 to 36 [deg]) in the vicinity of the position of the diffraction angle 2θ corresponding to tetraniobium trinitride (Nb₄N₃) by an average value [Iavg1] of intensities in a range of 32 to 34 [deg]. The second ratio is a ratio [Imax2/Iavg2] obtained by dividing a maximum peak intensity [Imax2] in a range (40-42 [deg]) in the vicinity of the position of the diffraction angle 2θ corresponding to tetraniobium trinitride (Nb₄N₃) by an average value [Iavg2] of intensities in a range of 38-40 [deg]. These two ratios are used independently and at least one must be used as the index. Both of them may be used as the index.

By examining a relationship between the above-mentioned two ratios obtained from the X-ray diffraction pattern of the thin film and the surface roughness and the film stress of the thin film, it has been found that the first ratio [Imax1/Iavg1] and the second ratio [Imax2/Iavg2] are preferably in a range of 7.0 or less and in a range of 1.0 or less, respectively. Furthermore, it has been found that the thin film need not satisfy both of the two ratios [Imax1/Iavg1] and [Imax2/Iavg2] in the X-ray diffraction pattern and that, if either one is satisfied, both the surface roughness and the film stress of the thin film can sufficiently be reduced.

Herein, “can be sufficiently reduced” described above means, in a case of the surface roughness, for example, root mean square roughness [Sq]=0.3 [nm] or less. The root mean square roughness (hereinafter referred to as surface roughness [Sq]) is a value obtained by measuring an inner region of a 1 [μm]-square as a measurement region with an atomic force microscope (AFM). For the film stress, the amount of deformation of the substrate (amount of substrate warpage) caused by formation of the thin film is 200 [nm] or less. The amount of deformation of the substrate is obtained by calculating a shape difference between a surface shape of the thin film and a surface shape of the substrate before forming the thin film, and is represented by a difference between the maximum height and the minimum height of the shape difference in an inner region of a 142 [mm]-square with respect to the center of the substrate. The root mean square roughness [Sq] is a parameter defined by ISO 25178 to evaluate the surface roughness and is a parameter obtained by extending a line roughness parameter [Rq] (root mean square roughness of a line) representing a two-dimensional surface texture defined by ISO 4287 and JIS B0601 to three dimensions (plane). A calculation formula is represented by the following equation (1).

$$[ Equation 1 ]$$

$$Sq = \sqrt{\frac{1}{A} \int {\int }_{A} {z}^{2} ( x , y ) dxdy} \qquad Equation ( 1 )$$

Now, an embodiment of the present disclosure will be described in detail with reference to the drawings. It should be noted that the following embodiment is one mode of embodying the present disclosure and is not intended to limit the present disclosure within the scope of the embodiment. In the drawings, the same or corresponding parts may be assigned with the same reference numerals and the description thereof may be simplified or omitted.

«Mask Blank and Reflective Mask»

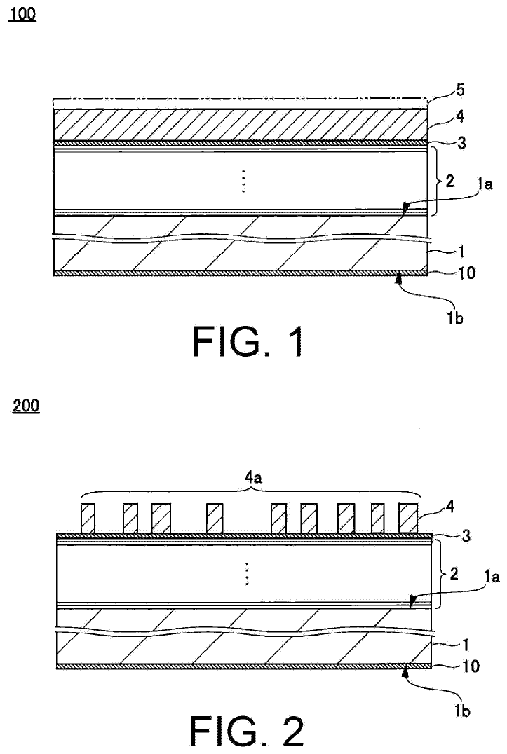

FIG. 1 is a cross-sectional view showing a configuration of a mask blank 100 according to the embodiment of the present disclosure. The mask blank 100 illustrated in the figure is an original plate of a reflective mask for EUV lithography using EUV light as exposure light. FIG. 2 is a cross-sectional view showing a configuration of a reflective mask 200 according to the embodiment of the present disclosure and is manufactured by processing the mask blank 100 shown in FIG. 1. Now, with reference to FIGS. 1 and 2, the configurations of the mask blank 100 and the reflective mask 200 according to the embodiment will be described.

The mask blank 100 shown in FIG. 1 includes a substrate 1, and a multilayer reflective film 2, a protective film 3, and a thin film 4 which are stacked on one main surface 1a of the substrate 1 in order from the side adjacent to the substrate 1. The thin film 4 is a film on which a transfer pattern is to be formed by processing. The mask blank 100 may have a structure in which an etching mask film 5 is formed on the thin film 4 as necessary. The mask blank 100 has a conductive film 10 on the other main surface (hereinafter referred to as a back surface 1b) of the substrate 1.

The reflective mask 200 shown in FIG. 2 is obtained by patterning the thin film 4 of the mask blank 100 shown in FIG. 1 as a transfer pattern 4a. Details of those parts constituting the mask blank 100 and the reflective mask 200 will be described below with reference to FIGS. 1 and 2.

<Substrate 1>

The substrate 1 preferably has a low thermal expansion coefficient in a range of 0±5 ppb/° C. in order to prevent distortion of the transfer pattern 4a due to heat generation during exposure by EUV light (EUV exposure) using the reflective mask 200. As a material having a low thermal expansion coefficient in this range, for example, SiO₂—TiO₂-based glass, multi-component glass ceramics, and the like may be used. The transfer pattern 4a is a pattern formed by processing the thin film 4 as described above.

The main surface 1a of the substrate 1 is surface-treated so as to have a high flatness from the viewpoint of obtaining pattern transfer accuracy and position accuracy in the EUV exposure using the reflective mask 200. In a case of the EUV exposure, the flatness is preferably 0.1 μm or less, more preferably 0.05 μm or less, particularly preferably 0.03 μm or less in a region of 132 mm×132 mm on the main surface 1a of the substrate 1.

The back surface 1b of the substrate 1 is electrostatically chucked when the reflective mask 200 is set in an exposure apparatus, and preferably has a flatness of 0.1 μm or less, more preferably 0.05 μm or less, particularly preferably 0.03 μm or less in a region of 132 mm×132 mm. The back surface 1b of the mask blank 100 preferably has a flatness of 1 μm or less, more preferably 0.5 μm or less, particularly preferably 0.3 μm or less in a region of 142 mm×142 mm.

A level of surface smoothness of the substrate 1 is also an extremely important item. The surface roughness of the main surface 1a of the substrate 1 is preferably 0.1 nm or less in root mean square roughness [Sq]. The surface smoothness can be measured by an atomic force microscope.

Furthermore, the substrate 1 preferably has high rigidity in order to suppress deformation of the films formed on the main surface 1a and the back surface 1b due to the film stress. In particular, the substrate 1 preferably has a high Young's modulus of 65 GPa or more.

<Multilayer Reflective Film 2>

The multilayer reflective film 2 is formed on the main surface 1a and reflects the EUV light as the exposure light at a high reflectance. The multilayer reflective film 2 provides a function of reflecting the EUV light in the reflective mask 200 formed using the mask blank 100, and is a multilayer film formed by periodically stacking respective layers mainly composed of elements having different refractive indices.

In general, a multilayer film in which thin films (high refractive index layers) of a light element as a high refractive index material or a compound thereof, and thin films (low refractive index layers) of a heavy element as a low refractive index material or a compound thereof, are alternately stacked in about 40 to 60 periods is used as the multilayer reflective film 2. The multilayer film may include a plurality of periods of stacked structures of high/low refractive index layers where one period includes a high refractive index layer and a low refractive index layer stacked in this order from the side adjacent to the substrate 1. Alternatively, the multilayer film may include a plurality of periods of stacked structures of low/high refractive index layers where one period includes a low refractive index layer and a high refractive index layer stacked in this order from the side adjacent to the substrate 1. Preferably, an outermost surface layer of the multilayer reflective film 2, that is, a surface layer of the multilayer reflective film 2 on the side opposite from the substrate 1, is a high refractive index layer. When the multilayer film described above includes a plurality of periods of stacked structures of the high/low refractive index layers where one period includes a high refractive index layer and a low refractive index layer stacked in this order from the side adjacent to the substrate 1, an uppermost layer is a low refractive index layer. In this case, when the low refractive index layer constitutes the outermost surface of the multilayer reflective film 2, the low refractive index layer is easily oxidized, reducing the reflectance of the reflective mask 200. Therefore, it is preferable that the multilayer reflective film 2 further comprises another high refractive index layer formed on the low refractive index layer as the uppermost layer. On the other hand, when the multilayer film described above includes a plurality of periods of stacked structures of low/high refractive index layers where one period includes a low refractive index layer and a high refractive index layer stacked in this order from the side adjacent to the substrate 1, the uppermost layer is a high refractive index layer. Therefore, this structure need not be changed.

In this embodiment, a layer containing silicon (Si) is used as the high refractive index layer. As a material containing Si, elemental Si and Si compounds containing boron (B), carbon (C), nitrogen (N), and oxygen (O) in addition to Si may be used. By using the layer containing Si as the high refractive index layer, the reflective mask 200 for the EUV lithography, having excellent EUV light reflectance is obtained. Furthermore, in the present embodiment, a glass substrate is preferably used as the substrate 1. Si is excellent also in adhesion to the glass substrate. As the low refractive index layer, an elemental metal selected from molybdenum (Mo), ruthenium (Ru), rhodium (Rh), and platinum (Pt) or an alloy thereof is used. For example, as the multilayer reflective film 2 for the EUV light having a wavelength of 13 nm to 14 nm, a Mo/Si periodically stacked film is preferably used in which Mo films and Si films are alternately stacked in about 40 to 60 periods. The high refractive index layer as the uppermost layer of the multilayer reflective film 2 may be formed of silicon (Si).

The reflectance of the multilayer reflective film 2 alone is usually 65% or more, and the upper limit is usually 73%. A film thickness of each constituent layer of the multilayer reflective film 2 and the number of periods may be appropriately selected depending on an exposure wavelength, and are selected so as to satisfy the Bragg's reflection law. Although a plurality of high refractive index layers and a plurality of low refractive index layers are present in the multilayer reflective film 2, the film thicknesses may not be the same among the high refractive index layers and among the low refractive index layers. In addition, the film thickness of the Si layer at the outermost surface of the multilayer reflective film 2 can be adjusted within a range not decreasing the reflectance. The film thickness of the Si layer (high refractive index layer) at the outermost surface may be in a range from 3 nm to 10 nm.

Methods of forming the multilayer reflective film 2 are known in the art. For example, by ion beam sputtering, each layer of the multilayer reflective film 2 can be formed. In the case of the Mo/Si periodic multilayer film described above, a Si film having a thickness of about 4.2 nm is first formed on the substrate 1 using an Si target, for example, by ion beam sputtering. Thereafter, a Mo film having a thickness of about 2.8 nm is formed using a Mo target. With the Si film/Mo film as one period, 40 to 60 periods are stacked to form the multilayer reflective film 2 (the outermost surface layer is the Si layer). It is noted here that, when the multilayer reflective film 2 includes, for example, 60 periods, the reflectance for the EUV light can be increased although the number of steps increases as compared with 40 periods. In addition, it is preferable to supply krypton (Kr) ion particles from an ion source during formation of the multilayer reflective film 2 and to form the multilayer reflective film 2 by ion beam sputtering.

<Protective Film 3>

The protective film 3 is a film provided to protect the multilayer reflective film 2 from etching and cleaning when the mask blank 100 is processed to manufacture the reflective mask 200 for the EUV lithography. The protective film 3 is provided on the multilayer reflective film 2 in contact with the multilayer reflective film 2 or through another film. The protective film 3 also serves to protect the multilayer reflective film 2 when black defects in the transfer pattern 4a are repaired in the reflective mask 200 using electron beams (EB).

Although FIG. 1 and FIG. 2 show a case where the protective film 3 is one layer, the protective film 3 may have a stacked structure of two or more layers. The protective film 3 is formed of a material resistant to an etchant for use in patterning the thin film 4 and to a cleaning liquid. By forming the protective film 3 on the multilayer reflective film 2, it is possible to suppress a damage to the surface of the multilayer reflective film 2 when the reflective mask 200 is manufactured using the substrate 1 having the multilayer reflective film 2 and the protective film 3. Therefore, reflectance characteristics of the multilayer reflective film 2 with respect to the EUV light become excellent.

In the following, the case where the protective film 3 is one layer will be described by way of example. When the protective film 3 includes a plurality of layers, the property of the material of the uppermost layer (the layer in contact with the thin film 4) of the protective film 3 becomes important in a relationship with the thin film 4.

In the mask blank 100 of this embodiment, a material resistant to an etching gas used in dry etching for patterning the thin film 4 formed on the protective film 3 may be selected as a material of the protective film 3.

The protective film 3 preferably contains ruthenium (Ru). The material of the protective film 3 may be a Ru elemental metal or a Ru alloy containing ruthenium (Ru) and at least one metal selected from titanium (Ti), niobium (Nb), molybdenum (Mo), zirconium (Zr), yttrium (Y), rhodium (Rh), boron (B), lanthanum (La), cobalt (Co), and rhenium (Re), and may contain nitrogen. On the other hand, as the protective film 3, a material selected from a silicon-based material, such as silicon (Si), a material containing silicon (Si) and oxygen (O), a material containing silicon (Si) and nitrogen (N), and a material containing silicon (Si), oxygen (O), and nitrogen (N), may be used.

In the EUV lithography, there are few materials transparent to the EUV light as the exposure light. Therefore, it is technically difficult to arrange a dust-proof mask (EUV pellicle) that prevents adhesion of foreign matters, on a surface of the reflective mask 200 on which the transfer pattern 4a is formed. From this, in the EUV lithography, a pellicle-less operation without using a dust-proof mask becomes mainstream. In the EUV lithography, exposure contamination occurs such as formation of a carbon film or growth of an oxide film on the reflective mask 200 by EUV exposure. Therefore, at a stage when the reflective mask 200 is used in manufacture of a semiconductor device, cleaning must be frequently performed to remove foreign matters and contamination on the mask. Accordingly, the reflective mask 200 is required to have extraordinary mask cleaning resistance in comparison with a transmissive mask for typical photolithography. By the reflective mask 200 having the protective film 3, the cleaning resistance to the cleaning liquid can be increased.

The film thickness of the protective film 3 is not particularly limited as long as the function of protecting the multilayer reflective film 2 is fulfilled. From the viewpoint of the reflectance for the EUV light, the film thickness of the protective film 3 is preferably 1.0 nm or more and 8.0 nm or less, more preferably 1.5 nm or more and 6.0 nm or less.

As a method for forming the protective film 3, those similar to known film forming methods may be used without particular limitation. Specific examples include various types of sputtering methods, such as DC sputtering, RF (Radio Frequency) sputtering, and ion beam sputtering, and atomic layer deposition (ALD).

<Thin Film 4 and Transfer Pattern 4a>

The thin film 4 is a film used as an absorber film for absorbing the EUV light, and serves as a film for forming the transfer pattern 4a of the reflective mask 200 constructed using the mask blank 100. The transfer pattern 4a is formed by patterning the thin film 4. In this embodiment, the thin film 4 of the mask blank 100 contains at least tantalum (Ta), niobium (Nb), and nitrogen (N). The thin film 4 is a tantalum (Ta)-niobium (Nb)-based material containing at least nitrogen (N), and may contain, for example, boron (B) as another material.

The thin film 4 has a crystal structure which is preferably microcrystalline or an amorphous structure. As will be shown in following examples also, it has been found that the crystallinity of the thin film 4 is reduced by making the tantalum (Ta)-niobium (Nb)-based material contain nitrogen (N). However, the degree of reduction of crystallinity has low correlation with the composition of tantalum (Ta), niobium (Nb), and nitrogen (N) of the thin film. Therefore, the thin film 4 is defined by the X-ray diffraction pattern.

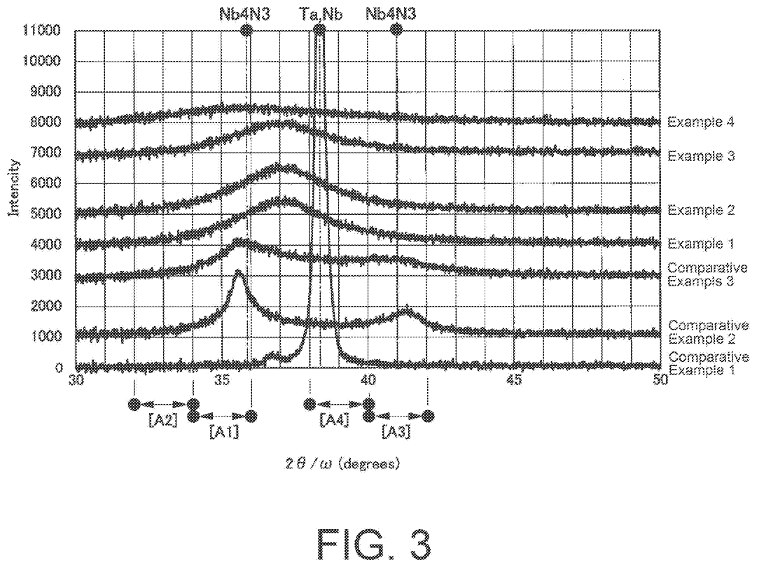

Specifically, in the thin film 4, the X-ray diffraction pattern obtained by Out-of-Plane measurement of the X-ray diffraction satisfies at least one of the following physical properties (a) and (b). FIG. 3 is a diagram showing the X-ray diffraction pattern for explaining physical properties of the thin film of the mask blank according to the embodiment of the present disclosure. Now, referring to FIG. 3, the physical properties (a) and (b) of the thin film 4 related to the X-ray diffraction will be described.
(a) [Imax1]/[Iavg1])≤7.0 where [Imax1] represents the maximum diffraction intensity at diffraction angles 2θ within a range [A1] of 34 degrees or more and 36 degrees or less in the X-ray diffraction pattern, and [Iavg1] represents the average diffraction intensity at diffraction angles 2θ within a range [A2] of 32 degrees or more and 34 degrees or less. The range [A1] is a range in the vicinity of a position of the diffraction angle 2θ corresponding to tetraniobium trinitride (Nb₄N₃). The range [A2] is a range of the diffraction angle 2θ [deg] within which the effect of the peak corresponding to tetraniobium trinitride (Nb₄N₃) is relatively small.
(b) ([Imax2]/[Iavg2])≤1.0 where [Imax2] represents the maximum diffraction intensity at diffraction angles 2θ within a range [A3] of 40 degrees or more and 42 degrees or less in the X-ray diffraction pattern, and [Iavg2] represents the average diffraction intensity at diffraction angles 8 within a range [A4] of 38 degrees or more and 40 degrees or less. The range [A3] is a range in the vicinity of a position of the diffraction angle 2θ corresponding to tetraniobium trinitride (Nb₄N₃). The range [A4] is a range of the diffraction angle 2θ [deg] within which the effect of the peak corresponding to tetraniobium trinitride (Nb₄N₃) is relatively small.

In the thin film 4, it is preferable that, when the diffraction angle 2θ in the X-ray diffraction pattern is within a range of 30 degrees or more and 50 degrees or less, the diffraction intensity becomes maximum at the diffraction angle 2θ within a range of 38 degrees or less.

The thin film 4 as described above is formed by sputtering and satisfies at least one of the above-mentioned physical properties (a) and (b) related to the X-ray diffraction by adjusting the environment (flow rate of sputtering gas, sputtering gas pressure, etc.) in the film forming chamber.

In the thin film 4 having the above-mentioned physical properties related to the X-ray diffraction, the surface roughness and the film stress are suppressed to be low as will be described in the following examples. Specifically, in the thin film 4 having the film thickness of about 50 nm, the surface roughness [Sq] (root mean square roughness) is less than 0.3 [nm]. The root mean square roughness [Sq] is a value obtained by measuring, for the thin film formed on a test substrate, an inner region of a 1 [μm] square as a measurement region by an atomic force microscope (AFM). As regards the film stress of the thin film 4, the amount of deformation of the test substrate due to the formation of the thin film 4 is 200 [nm] or less. The amount of deformation of the test substrate is obtained by calculating a shape difference between a surface shape of the thin film 4 and a surface shape of the test substrate before forming the thin film 4, and is represented by a difference between the maximum height and the minimum height of the shape difference in an inner region of a 142 [mm]-square with respect to a center of the test substrate. The test substrate is formed of a SiO₂—TiO₂-based glass similar to the substrate 1 of the mask blank 100 and is a 6025 size (about 152 mm×152 mm×6.35 mm) substrate with both main surfaces polished.

The thin film 4 having the physical properties related to the X-ray diffraction as described above is a film low in crystallinity, i.e., a microcrystalline film or an amorphous film. Therefore, the transfer pattern 4a of the reflective mask 200 obtained by patterning the thin film 4 is a pattern whose edge roughness is reduced to be low. Furthermore, the transfer pattern 4a of the reflective mask 200 obtained by patterning the thin film 4 low in film stress as described above is a pattern excellent in forming position accuracy. As a result, it is possible to improve transfer accuracy of the pattern in the EUV lithography using the reflective mask 200.

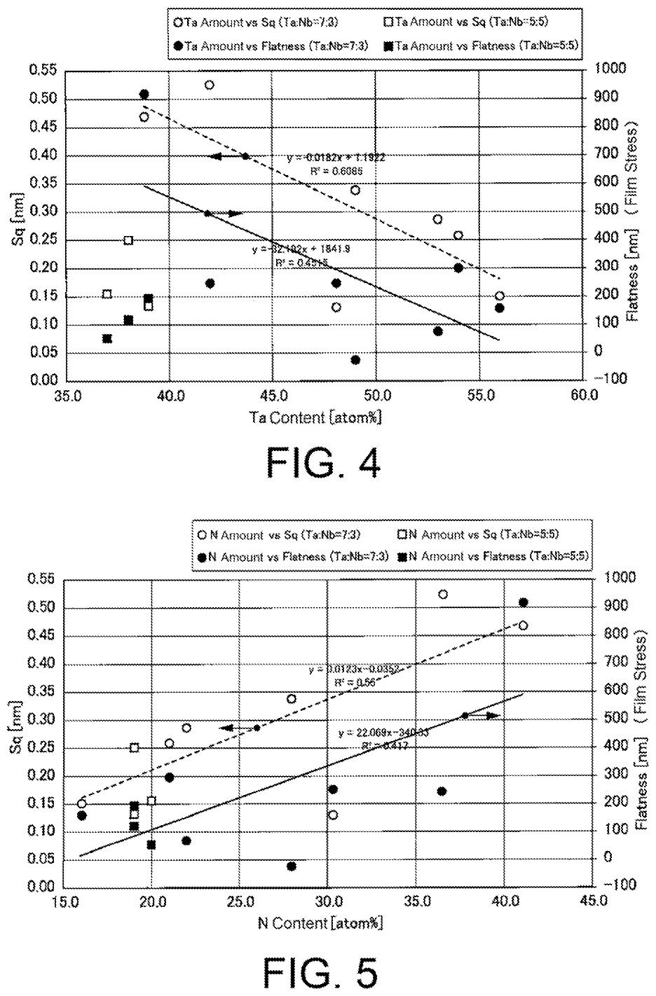

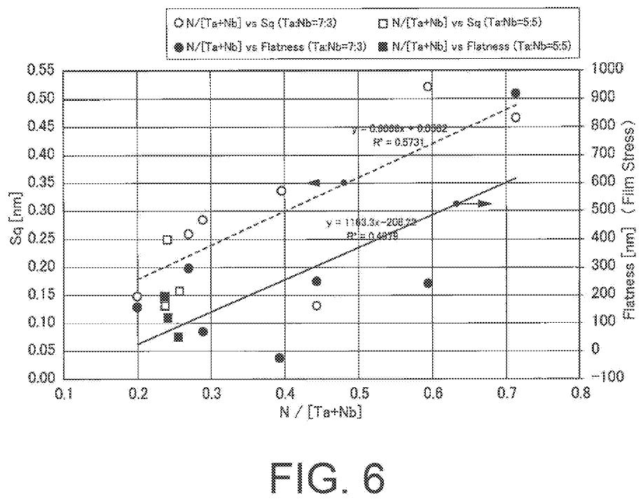

FIGS. 4-6 are graphs (1)-(3) showing the relationship between the composition of a tantalum (Ta)-niobium (Nb)-based material used as a thin film material and the surface roughness and the film stress of the thin film. FIG. 4 is a graph related to a thin film formed of tantalum (Ta)-niobium (Nb), and FIGS. 5 and 6 are graphs related to a thin film formed of tantalum (Ta)-niobium (Nb) and containing nitrogen (N). In each graph, a horizontal axis shows the composition of the thin film, a left vertical axis represents the surface roughness [Sq] (root mean square roughness), and a right vertical axis represents the film stress described above. For each thin film, a composition ratio was adjusted by changing a composition and a flow rate of a gas used for film formation in sputtering film formation using a target having a tantalum (Ta):niobium (Nb) composition ratio shown in each graph. Each thin film has a film thickness of 50 nm. The composition ratio of each thin film is an average value of the composition ratios obtained by analysis in a depth direction by X-ray Photoelectron Spectroscopy (XPS) after film formation.

As seen in FIGS. 4-6, it is understood that the thin film of the tantalum (Ta)-niobium (Nb)-based material has a low correlation between the composition and the surface roughness and the film stress, and that the surface roughness of the film and the film stress are difficult to be reduced using the composition as an index.

In the thin film 4 having the above-mentioned physical property (a) or (b) related to the X-ray diffraction, a ratio of a content [atomic %] of niobium (Nb) to a total content [atomic %] of tantalum (Ta) and niobium (Nb) is less than 0.6, as will be described in connection with the following examples. Furthermore, a content of nitrogen (N) in the thin film 4 is 30 atomic % or less. A total content of tantalum (Ta), niobium (Nb), and nitrogen (N) in the thin film 4 is 95 atomic % or more. Furthermore, when the thin film 4 contains boron (B), a total content of tantalum (Ta), niobium (Nb), nitrogen (N), and boron (B) in the thin film 4 is 95 atomic % or more.

The thin film 4 having the above-mentioned composition is low in refractive index [n] and extinction coefficient [k]. Also, it is understood that the tantalum (Ta)-niobium (Nb)-based material (TaNbN, TaNbBN) containing nitrogen (N) tends to be lower in extinction coefficient [k] as the content of niobium (Nb) increases.

For example, the thin film 4 having the physical property related to the X-ray diffraction and the composition range described above has a refractive index [n] of 0.95 or less at the wavelength of the EUV light. Furthermore, the thin film 4 has an extinction coefficient [k] of 0.03 or less at the wavelength of the EUV light. Such a thin film 4 is used as a phase shift film and, when the transfer pattern 4a of the reflective mask 200 is a phase shift pattern, the film thickness can be set to a range of smaller values. Therefore, when the reflective mask 200 is a phase shift mask, the transfer pattern 4a as the phase shift pattern can be lowered in profile to suppress occurrence of the shadowing effect in the reflective mask 200.

In the thin film 4 used as the phase shift film, a film thickness is adjusted so as to provide a reflectance as follows. Specifically, when the transfer pattern 4a of the reflective mask 200 is a phase shift pattern, the thin film 4 is configured as a phase shift film. Such a thin film 4 absorbs the EUV light and reflects a part of the EUV light at a level that does not adversely affect the pattern transfer. Furthermore, at a portion of the reflective mask 200 where the transfer pattern 4a is formed, the protective film 3 is exposed at an opening portion where the thin film 4 is removed. Therefore, the EUV light emitted to the reflective mask 200 is reflected by the surface of the thin film 4 and by the multilayer reflective film 2 via the protective film 3 exposed from the thin film 4.

When the transfer pattern 4a is a phase shift pattern, the material and the film thickness of the thin film 4 are set so that reflected EUV light at the surface of the thin film 4 and reflected EUV light at the opening portion from which the thin film 4 is removed have a desired phase difference. This phase difference is about 130 degrees to about 230 degrees. The reflected lights inverted with a phase difference near 180 degrees or near 220 degrees interfere with each other at a pattern edge to thereby improve image contrast of a projected optical image. With the improvement of the image contrast, a resolution increases and various tolerances related to exposure, such as exposure tolerance and focus tolerance, are widened.

In order to obtain such a phase shift effect, relative reflectance for the EUV light at the surface of the thin film 4 is preferably 2% to 40%, more preferably 6% to 35%, further preferably 15% to 35%, particularly preferably 15% to 25% although depending on a pattern or an exposure condition. It is noted here that the relative reflectance of the transfer pattern 4a is a reflectance for the EUV light reflected from the thin film 4 where the reflectance for the EUV light reflected by the portion without the thin film 4 is assumed to be 100%.

In order to obtain the phase shift effect, an absolute reflectance of the thin film 4 (or the transfer pattern 4a to be the phase shift pattern) with respect to the EUV light is preferably 4% to 27%, more preferably 10% to 17%, although depending on the pattern or the exposure condition. The film thickness is determined so that the above-mentioned absolute reflectance is obtained.

The thin film 4 as described above may also be used as an absorber film for a binary mask by adjusting the film thickness.

<Etching Mask Film 5>

As shown in FIG. 1, the etching mask film 5 is a layer formed on the thin film 4 in the mask blank 100 or in contact with the surface of the thin film 4, and serves as a mask pattern when the thin film 4 is patterned. As shown in FIG. 2, the etching mask film 5 is a layer which has been removed and is not present in the reflective mask 200.

As a material of the etching mask film 5, a material which provides high etching selectivity of the thin film 4 to the etching mask film 5 is used. It is noted here that “the etching selectivity of B to A” refers to an etching rate ratio between a layer A which need not be etched (a layer to serve as a mask) and a layer B which need to be etched. Specifically, the etching selectivity is defined by a formula “Etching Selectivity of B to A=Etching Rate of B/Etching Rate of A”. Also, “high selectivity” means that the value of the selectivity defined above is large relative to an object to be compared. The etching selectivity of the thin film 4 to the etching mask film 5 is preferably 1.5 or more, more preferably 3 or more.

In this embodiment, the thin film 4 formed of the material containing at least tantalum (Ta), niobium (Nb), and nitrogen (N) can be etched by dry etching with a chlorine-based gas. In the dry etching using the chlorine-based gas as an etchant, a material having high etching selectivity with respect to the thin film 4 formed of a Ta—Nb-based material containing N may be exemplified by a material containing chromium (Cr). Specific examples of the material containing chromium (Cr) include, for example, a material containing chromium and one or more elements selected from nitrogen, oxygen, carbon, and boron, as a chromium-containing material forming the etching mask film. For example, CrN, CrON, CrCN, CrCON, CrBN, CrBON, CrBCN, CrBOCN, and the like are presented. These materials may contain a metal other than chromium to the extent that the effect of the present disclosure is obtained. As a film forming method of the etching mask film 5, for example, magnetron sputtering or ion beam sputtering using a target of chromium (Cr) may be used.

The film thickness of the etching mask film 5 is desirably 2 nm or more from the viewpoint of obtaining a function as an etching mask for accurately forming the transfer pattern on the thin film 4. The film thickness of the etching mask film 5 is desirably 15 nm or less from the viewpoint of reducing the film thickness of a resist film formed on the etching mask film 5 when the mask blank 100 is processed to manufacture the reflective mask 200.

<Conductive Film 10>

The conductive film 10 is a film for attaching the reflective mask 200 to the exposure apparatus by electrostatic chucking. An electric characteristic (sheet resistance) required by the conductive film 10 for electrostatic chucking is typically 100Ω/□ (Ω/Square) or less. As a method of forming the conductive film 10, magnetron sputtering or ion beam sputtering using a target of metal, such as chromium (Cr) and tantalum (Ta), and an alloy thereof, may be used.

The chromium (Cr)-containing material of the conductive film 10 is preferably a Cr compound containing Cr and further containing at least one selected from boron (B), nitrogen (N), oxygen (O), and carbon (C).

As the tantalum (Ta)-containing material of the conductive film 10, it is preferable to use Ta (tantalum), a Ta-containing alloy, or a Ta compound containing either Ta or a Ta-containing alloy and at least one of boron, nitrogen, oxygen, and carbon.

The thickness of the conductive film 10 is not particularly limited as long as its function for electrostatic chucking is satisfied. The thickness of the conductive film 10 is typically 10 nm to 200 nm. The conductive film 10 also serves to perform stress adjustment on the back surface 1b of the mask blank 100. Thus, the conductive film 10 is adjusted so that the flat mask blank 100 and the flat reflective mask 200 can be obtained by keeping balance with stress from various films formed on the main surface 1a.

<Method of Manufacturing Reflective Mask>

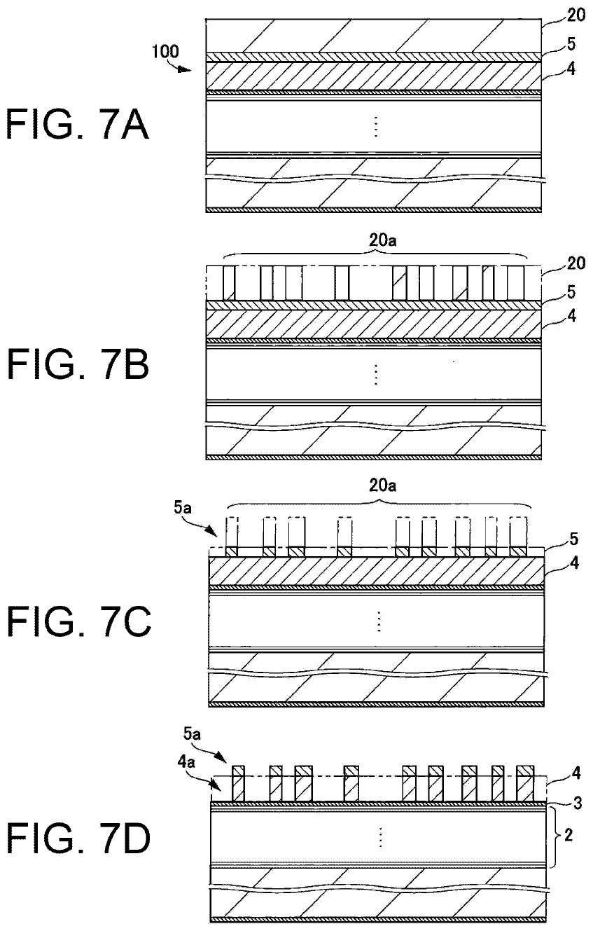

FIGS. 7A to 7D are manufacturing process diagrams showing a manufacturing method of a reflective mask of the present disclosure, and is a view showing steps for manufacturing the reflective mask 200 shown in FIG. 2 by using the mask blank 100 shown in FIG. 1. The method of manufacturing the reflective mask will be described below with reference to FIG. 7.

First, as shown in FIG. 7A, a mask blank 100 is prepared. This mask blank 100 is the mask blank 100 described using FIG. 1 and, for example, includes the etching mask film 5 formed on the thin film 4. However, if the mask blank 100 does not have the etching mask film 5, then the etching mask film 5 is formed on the thin film 4. Thereafter, a resist film 20 is formed on the etching mask film 5, for example, by spin coating. Sometimes, the mask blank 100 is provided with the resist film 20. In this case, the film forming step of the resist film 20 is not required.

Next, as shown in FIG. 7B, the resist film 20 is subjected to lithography to form a resist pattern 20a obtained by patterning the resist film 20. In the lithography, for example, exposure by electron beam writing, development, and rinsing are performed.

Next, as shown in FIG. 7C, the etching mask film 5 is etched using the resist pattern 20a as a mask to form an etching mask pattern 5a. Thereafter, the resist pattern 20a is removed by ashing, a resist remover, or the like.

Next, as shown in FIG. 7D, the thin film 4 is etched using the etching mask pattern 5a as a mask to form the transfer pattern 4a. In this step, since a constituent material of the thin film 4 is a tantalum (Ta)-niobium (Nb)-based material containing at least nitrogen (N), etching is carried out using a chlorine-based gas containing oxygen or a chlorine-based gas as an etching gas. In this etching, the protective film 3 made of a material containing ruthenium (Ru) or made of silicon oxide (SiO₂) serves as an etching stopper so that the multilayer reflective film 2 is prevented from an etching damage. In addition, since the protective film 3 itself also has etching resistance, surface roughening does not occur in the protective film 3.

Thereafter, by removing the etching mask pattern 5a, the reflective mask 200 shown in FIG. 2 is obtained. The etching mask pattern 5a is removed by wet cleaning using an acidic or alkaline aqueous solution. In this wet cleaning also, the multilayer reflective film 2 is prevented by the protective film 3 from being damaged.

The transfer pattern 4a of the reflective mask 200 obtained as described above is formed by etching the thin film 4 having small surface roughness and small film stress. Therefore, sidewall roughness is suppressed to be small and shape accuracy and position accuracy are excellent. The thin film 4 constituting the transfer pattern 4a is a film small in refractive index [n] and extinction coefficient [k]. Therefore, when the transfer pattern 4a is used as a phase shift pattern, the film thickness of the transfer pattern 4a can be reduced, so that a reflective phase shift mask capable of suppressing occurrence of the shadowing effect is obtained.

<Semiconductor Device Manufacturing Method>

A semiconductor device manufacturing method according to the present disclosure is characterized by using the reflective mask 200 described above and performing exposure transfer of the transfer pattern 4a of the reflective mask 200 to a resist film on a substrate. The semiconductor device manufacturing method is carried out as follows.

First, a substrate on which a semiconductor device is to be formed is prepared. The substrate may be, for example, a semiconductor substrate, a substrate having a semiconductor thin film. Furthermore, a microprocessed film may be formed on these substrates. A resist film is formed on the prepared substrate. The resist film is subjected to pattern exposure using the reflective mask 200 of the present disclosure to perform exposure transfer of the transfer pattern 4a formed on the reflective mask 200 to the resist film. In this step, the EUV light is used as the exposure light.

Thereafter, the resist film after exposure transfer of the transfer pattern 4a is developed to form a resist pattern. A process of etching a surface layer of the substrate with the resist pattern used as a mask and introducing impurities is performed. After the process is finished, the resist pattern is removed.

By performing the above-mentioned processes and further carrying out necessary machining processes, the semiconductor device is completed.

In the manufacture of the semiconductor device as described above, pattern exposure with the EUV light as exposure light is performed using the reflective mask 200 having the transfer pattern 4a excellent in shape accuracy, so that a resist pattern having an accuracy which sufficiently satisfies an initial design specification can be formed on the substrate. When the reflective mask 200 is a reflective phase shift mask, it is possible to form a resist pattern excellent in shape accuracy and position accuracy because occurrence of the shadowing effect is suppressed. Thus, when a circuit pattern is formed by dry-etching an underlayer film using the pattern of the resist film as a mask, it is possible to form a high-accuracy circuit pattern without short-circuiting or disconnection due to insufficient accuracy.

### EXAMPLE

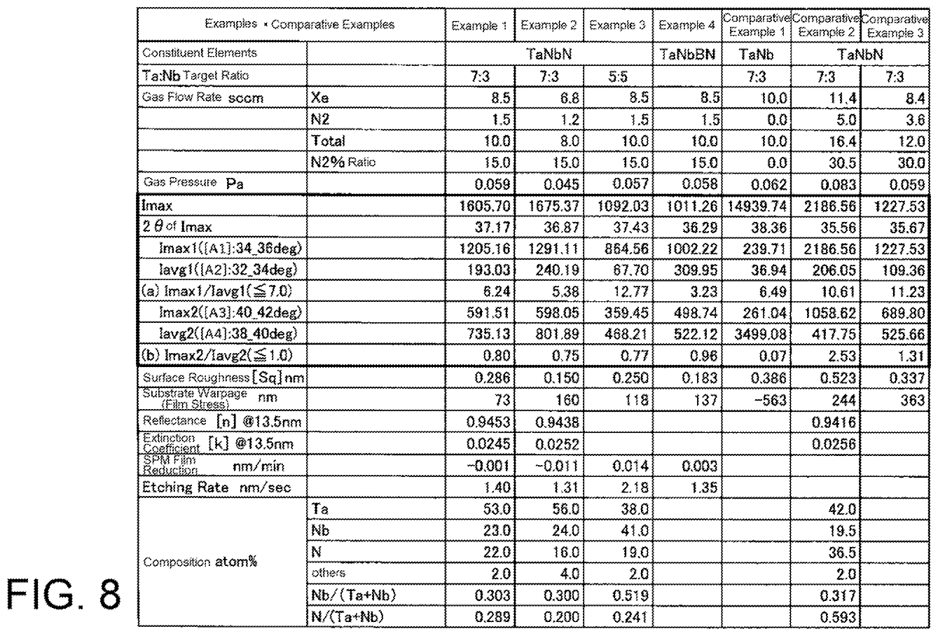

Next, Examples 1-4 to which the present disclosure is applied and Comparative Examples 1-3 will be described. FIG. 8 is a diagram showing forming conditions of thin films in mask blanks of Examples and Comparative Examples and physical properties and compositions of the thin films which were formed. Examples 1 to 4 and Comparative Examples 1 to 3 will be described below with reference to FIG. 1 mentioned above and FIG. 8.

<Formation of Mask Blank>

### Examples 1-3

The mask blanks 100 of Examples 1-3 were prepared as follows. First, a SiO₂—TiO₂-based glass substrate, which is a low-thermal-expansion glass substrate of 6025 size (about 152 mm×152 mm×6.35 mm) with both main surfaces polished, was prepared as the substrate 1. Polishing including a rough polishing step, a precision polishing step, a local processing step, and a touch polishing step was performed so that the both main surfaces of the substrate 1 became flat and smooth.

Next, assuming that one main surface of the substrate 1 is the back surface 1b, the conductive film 10 of a CrN film was formed on the back surface 1b by magnetron sputtering (reactive sputtering). The conductive film 10 was formed to a film thickness of 20 nm using a Cr target in a gas mixture atmosphere of an argon (Ar) gas and a nitrogen (N₂) gas.

Next, assuming that the other surface opposite from the back surface 1b with the conductive film 10 formed thereon is the main surface 1a of the substrate 1, the multilayer reflective film 2 was formed on the main surface 1a. The multilayer reflective film 2 formed on the substrate 1 was a periodic multilayer reflective film of molybdenum (Mo) and silicon (Si) in order to adapt the multilayer reflective film 2 to the EUV light of a wavelength of 13.5 nm. The multilayer reflective film 2 was formed by alternately stacking Mo layers and Si layers on the substrate 1 by ion beam sputtering using a Mo target and a Si target in a krypton (Kr) gas atmosphere. A Si film was first formed to a film thickness of 4.2 nm and, subsequently, a Mo film was formed to a film thickness of 2.8 nm. Assuming this as one period, 40 periods of films were similarly stacked. Finally, the Si film was formed to a film thickness of 4.0 nm to form the multilayer reflective film 2.

Subsequently, by RF sputtering using a SiO₂ target in a Ar gas atmosphere, the protective film 3 comprising a SiO₂ film was formed on the surface of the multilayer reflective film 2 to a film thickness of 2.6 nm.

Next, a film (TaNbN film) containing tantalum (Ta), niobium (Nb), and nitrogen (N) was formed as the thin film 4 by DC magnetron sputtering. In this step, using a sputtering target having a tantalum (Ta):niobium (Nb) target ratio (atomic % ratio) shown in FIG. 8 in a film-forming gas atmosphere of a xenon gas (Xe) and a nitrogen gas (N₂), the thin film 4 was formed to a film thickness of 50 nm. The gas flow rate and the gas pressure during film formation are as shown in FIG. 8.

### Example 4

The mask blank 100 was prepared by similar steps to those of the mask blank 100 of Examples 1-3 except that, in the formation of the thin film 4 in the steps of preparing the mask blank 100 of Examples 1-3, a film (TaNbBN film) further containing boron (B) was formed. In this case, in the formation of the thin film 4, by co-sputtering using two targets including a tantalum (Ta):boron (B) mixed target (Ta:B=4:1 atomic % ratio) and a niobium (Nb) target, the thin film 4 was formed to a film thickness of 50 nm in a film-forming gas atmosphere of a Xenon gas (Xe) and a nitrogen gas (N₂). The gas flow rate and the gas pressure during film formation are as shown in FIG. 8.

### Comparative Example 1

A mask blank was prepared by similar steps to those of the mask blank 100 of Examples 1 to 3 except that, in the formation of the thin film 4 in the steps of preparing the mask blank 100 of Examples 1 to 3, a film (TaNb film) containing tantalum (Ta) and niobium (Nb) without containing nitrogen (N) was formed. In this case, using a sputtering target having a tantalum (Ta):niobium (Nb) target ratio shown in FIG. 8 in a film-forming gas atmosphere of a xenon gas (Xe), a thin film was formed to a film thickness of 50 nm. The gas flow rate and the gas pressure during film formation are as shown in FIG. 8.

### Comparative Examples 2, 3

A mask blank was prepared by similar steps to those of the mask blank 100 of Examples 1 to 3 except that, in the formation of the thin film 4 in the steps of preparing the mask blank 100 of Examples 1-3, a film (TaNbN film) containing tantalum (Ta), niobium (Nb), and nitrogen (N) was formed with the gas flow rates of a xenon gas (Xe) and a nitrogen gas (N₂) changed as shown in FIG. 8. The gas flow rate and the gas pressure during film formation are as shown in FIG. 8.

<Evaluation of Thin Film in Each Mask Blank>

The film of each of the mask blanks prepared in Examples 1-4 and Comparative Examples 1-3 was directly formed on a substrate, and physical properties and a composition of each of the thin films of Examples 1-4 and Comparative Examples 1-3 were evaluated. The substrate was similar to that used in preparation of the mask blank.

<Physical Properties Related to X-Ray Diffraction>

Each of the thin films of Examples 1 to 4 and Comparative Examples 1 to 3 was analyzed by Out-of-Plane measurement of X-ray diffraction to measure an X-ray diffraction pattern. The results are shown in FIG. 3. Based on the X-ray diffraction patterns of Examples 1 to 4 and Comparative Examples 1 to 3 shown in FIG. 3, physical properties (a) and (b) related to X-ray diffraction of each thin film were calculated. The results are shown in FIG. 8 together. It is noted that, in the X-ray diffraction patterns of Examples 1 to 4 and Comparative Examples 1 to 3 shown in FIG. 3, reference values (origins) of diffraction intensities are changed so that differences among the respective X-ray diffraction patterns can easily be compared even illustrated in one graph. Imax and so on as actual measurement results are numerical values illustrated in FIG. 8.

As shown in FIGS. 3 and 8, each of the thin films of Examples 1 and 2 was a film (TaNbN film) containing nitrogen (N), tantalum (Ta), niobium (Nb) as the film forming materials, and was confirmed to be the thin film 4 which satisfies the conditions of both the physical properties (a) and (b) related to X-ray diffraction and constitutes the mask blank of the present disclosure. The thin film of Example 3 was similarly a TaNbN film and was confirmed to be the thin film 4 which satisfies the condition of the physical property (b) related to X-ray diffraction and constitutes the mask blank of the present disclosure. Further, the thin film of Example 4 was a film (TaNbBN film) containing boron (B), nitrogen (N), tantalum (Ta), niobium (Nb) as the film forming materials and was confirmed to be the thin film 4 which satisfies the conditions of both the physical properties (a) and (b) related to X-ray diffraction and constitutes the mask blank of the present disclosure.

On the other hand, the thin film of Comparative Example 1 is a film satisfying the conditions of both the physical properties (a) and (b) related to X-ray diffraction but is a tantalum (Ta)-niobium (Nb)-based film (TaNb film) without containing nitrogen (N) as the film forming materials. Therefore, the thin film does not correspond to the thin film 4 constituting the mask blank of the present disclosure.

Furthermore, each of the thin films of Comparative Examples 2 and 3 is a film (TaNbN film) containing nitrogen (N), tantalum (Ta), and niobium (Nb) as the film forming materials, but does not satisfy any of the conditions of the physical properties (a) and (b) related to X-ray diffraction. Therefore, it has been confirmed that the thin film does not correspond to the thin film 4 constituting the mask blank of the present disclosure.

<Surface Roughness and Film Stress>

Surface roughness and film stress of each of the thin films of Examples 1-4 and Comparative Examples 1-3 were measured. The results are shown in FIG. 8 together. As described above, the surface roughness [Sq] (root mean square roughness) is a value obtained by measuring, as a measurement region, an inner region of a 1-μm square by an AFM. The film stress is obtained by calculating a shape difference between the surface shape of the thin film and the surface shape of the substrate before formation of the thin film, and is represented by a difference (substrate warpage) between the maximum height and the minimum height of the shape difference in the inner region of the 142-mm square with respect to the center of the substrate. For measurement of each surface shape, a surface shape measuring device UltraFLAT200M (manufactured by Corning TROPEL) was used.

It has been found out that, as shown in FIG. 8, each of the thin films of Examples 1-4 has a surface roughness [Sq] (root mean square roughness) suppressed to be less than 0.3 [nm] and a film stress (substrate warpage) suppressed to be 200 [nm] or less. In contrast, each of the thin films of Comparative Examples 1-3 has a surface roughness [Sq] exceeding 0.3 [nm] and a film stress (substrate warpage) exceeding 200 [nm].

As a result of the above, it has been confirmed that applying the present disclosure provides a mask blank having a pattern-forming thin film with surface roughness and film stress suppressed to be low.

<Refractive Index and Extinction Coefficient>

As representative samples from Examples 1-4 and Comparative Examples 1-3, each of the thin films of Example 1, Example 2, and Comparative Example 2 was subjected to measurement of the refractive index [n] and the extinction coefficient [k] for EUV light (wavelength 13.5 nm). The results are shown in FIG. 8 together.

As shown in FIG. 8, both of the thin film 4 of Example 1 and the thin film of Comparative Example 2 had a refractive index [n] of 0.95 or less and an extinction coefficient [k] of 0.03 or less. As a result, when the reflective mask is formed using the thin film 4 of Example 1 as a phase shift pattern, the film thickness of the phase shift pattern of the reflective mask can be set to a range of smaller values. Thus, it has been confirmed that, when the reflective mask 200 is a phase shift mask, the transfer pattern 4a as the phase shift pattern is lowered in profile and an effect of suppressing occurrence of the shadowing effects of the reflective mask 200 is obtained.

<Cleaning Resistance and Etching Rate>

A cleaning resistance and an etching rate of each of the thin films of Examples 1-4 were measured. The cleaning resistance was measured as the amount of film reduction (SPM film reduction) of the thin film 4 in a state where the thin film 4 was exposed to a sulfuric acid-hydrogen peroxide aqueous solution (SPM cleaning liquid) used as a cleaning liquid for the mask blank and the reflective mask. As the etching rate, an etching speed of the thin film was measured in a state where the thin film 4 was exposed to a chlorine gas (Cl₂) atmosphere used as an etchant for the thin film 4 when the mask blank was processed to prepare a reflective mask. The results are shown in FIG. 8 together.

As shown in FIG. 8, it has been confirmed that each of the thin films of Examples 1-4 has SPM film reduction of a small value not greater than 0.015 (nm/min) and has a sufficient SPM resistance. Furthermore, it has been confirmed that the etching rate of each of the thin films of Examples 1 to 4 is 1.30 (nm/sec) or more, which is sufficiently high.

<Composition of Thin Film>

For each of the thin films of Examples 1 to 4 and the thin film of Comparative Example 2 as a representative sample from Comparative Examples 1 to 3, the composition ratio was analyzed by XPS analysis in a depth direction. The results are shown in FIG. 8 together.

As shown in FIG. 8, it has been confirmed that, in each of the thin films of Examples 1-4, the ratio of the content [atomic %] of niobium (Nb) to the total content [atomic %] of tantalum (Ta) and niobium (Nb) is less than 0.6. Furthermore, it has been confirmed that the content of nitrogen (N) is 30 atomic % or less. Each of the thin films of Examples 1 to 3 is a film containing tantalum (Ta), niobium (Nb), and nitrogen (N) and it has been confirmed that the total content thereof is 95 atomic % or more. In contrast, in the thin film of Comparative Example 2, the ratio of the content [atomic %] of niobium (Nb) to the total content [atomic %] of tantalum (Ta) and niobium (Nb) was less than 0.6 and the content of nitrogen (N) was 30 atomic % or more.

On the other hand, it is said that the thin film of Example 4 is a film substantially formed of tantalum (Ta), niobium (Nb), nitrogen (N), and boron (B) as will be understood from the above-mentioned film-forming conditions, and the total content thereof is 95 atomic % or more.

### DESCRIPTION OF REFERENCE SYMBOLS

1 . . . substrate
1a . . . main surface
2 . . . multilayer reflective film
3 . . . protective film (another film)
4 . . . thin film
4a . . . transfer pattern
100 . . . mask blank
200 . . . reflective mask

1. A mask blank comprising: a substrate; a multilayer reflective film above the substrate; and a pattern-forming thin film above the multilayer reflective film,
wherein the thin film contains tantalum, niobium, and nitrogen,
wherein an X-ray diffraction pattern obtained by analyzing the thin film by Out-of-Plane measurement of X-ray diffraction satisfies the relationship of at least one of Imax1/Iavg1≤7.0 and Imax2/Iavg2≤1.0, where Imax1 is a maximum value of diffraction intensity at a diffraction angle 2θ in a range of 34 to 36 degrees, Iavg1 is an average value of diffraction intensity at a diffraction angle 2θ in a range of 32 to 34 degrees, Imax2 is a maximum value of diffraction intensity at a diffraction angle 2θ in a range of 40 to 42 degrees, and Iavg2 is an average value of diffraction intensity at a diffraction angle 2θ in a range of 38 to 40 degrees.

2. The mask blank according to claim 1, wherein, at a diffraction angle 2θ within a range of 30 degrees or more and 50 degrees or less in the X-ray diffraction pattern, the thin film has a maximum diffraction intensity at a diffraction angle 2θ of 38 degrees or less.

3. The mask blank according to claim 1, wherein, in the thin film, a ratio of a content [atomic %] of niobium to a total content [atomic %] of tantalum and niobium is less than 0.6.

4. The mask blank according to claim 1, wherein a content of nitrogen in the thin film is 30 atomic % or less.

5. The mask blank according to claim 1, wherein a total content of tantalum, niobium, and nitrogen in the thin film is 95 atomic % or more.

6. The mask blank according to claim 1, wherein the thin film further contains boron.

7. The mask blank according to claim 6, wherein a total content of tantalum, niobium, boron, and nitrogen in the thin film is 95 atomic % or more.

8. The mask blank according to claim 1, wherein a refractive index of the thin film at an extreme ultraviolet wavelength is 0.95 or less.

9. The mask blank according to claim 1, wherein an extinction coefficient of the thin film at an extreme ultraviolet wavelength is 0.03 or less.

10. A reflective mask comprising a substrate: a multilayer reflective film above the substrate; and a thin film with a transfer pattern formed above the multilayer reflective film,
wherein the thin film contains tantalum, niobium, and nitrogen,
wherein an X-ray diffraction pattern obtained by analyzing the thin film by Out-of-Plane measurement of X-ray diffraction satisfies the relationship of at least one of Imax1/Iavg1≤7.0 and Imax2/Iavg2≤1.0, where Imax1 is a maximum value of diffraction intensity at a diffraction angle 2θ in a range of 34 to 36 degrees, Iavg1 is an average value of diffraction intensity at a diffraction angle 2θ in a range of 32 to 34 degrees, Imax2 is a maximum value of diffraction intensity at a diffraction angle 2θ in a range of 40 to 42 degrees, and Iavg2 is an average value of diffraction intensity at a diffraction angle 2θ in a range of 38 to 40 degrees.

11. The reflective mask according to claim 10, wherein, at a diffraction angle 2θ within a range of 30 degrees or more and 50 degrees or less in the X-ray diffraction pattern, the thin film has a maximum diffraction intensity at a diffraction angle 2θ of 38 degrees or less.

12. The reflective mask according to claim 10, wherein, in the thin film, a ratio of a content [atomic %] of niobium to a total content [atomic %] of tantalum and niobium is less than 0.6.

13. The reflective mask according to claim 10, wherein a content of nitrogen in the thin film is 30 atomic % or less.

14. The reflective mask according to claim 10, wherein a total content of tantalum, niobium, and nitrogen in the thin film is 95 atomic % or more.

15. The reflective mask according to claim 10, wherein the thin film further contains boron.

16. The reflective mask according to claim 15, wherein a total content of tantalum, niobium, boron, and nitrogen in the thin film is 95 atomic % or more.

17. The reflective mask according to claim 10, wherein a refractive index of the thin film at an extreme ultraviolet wavelength is 0.95 or less.

18. The reflective mask according to claim 10, wherein an extinction coefficient of the thin film at an extreme ultraviolet wavelength is 0.03 or less.

19. (canceled)

20. The mask blank according to claim 1, further comprising an etching mask film above the thin film and wherein the etching mask film comprises chromium and one or more elements selected from a group consisting of nitrogen, oxygen, carbon, and boron.
